(19) United States
(12) Patent Application Publication
(10) Pub. No.: US 2008/0012102 A1
(43) Pub. Date: Jan. 17, 2008

(54) SEMICONDUCTOR-INTEGRATED ELECTRONIC DEVICE HAVING A PLURALITY OF LEADS

(75) Inventors: Fabio Marchisi, Peschiera Borromeo (IT); Giuliano Angelo Babulano, Tremestieri Etneo (IT)

Correspondence Address: SEED INTELLECTUAL PROPERTY LAW GROUP PLLC, 701 FIFTH AVENUE, SUITE 5400, SEATTLE, WA, 98104-7092, US

(73) Assignee: STMicroelectronics S.r.l., Agrate Brianza (IT)

(21) Appl. No.: 11/774,416

(22) Filed: Jul. 6, 2007

(30) Foreign Application Priority Data
Jul. 7, 2006 (EP) 06425477.4

(51) Int. Cl. H01L 23/495

(52) U.S. Cl. 257/668; 257/E23.031

(57) ABSTRACT

A semiconductor-integrated electronic device comprises a body and a plurality of leads, adjacent and in spaced relationship to each other, projecting from at least one edge of the body. The device further comprises a spacer device which comprises a plurality of insulating teeth interposed between the plurality of leads, so as to form an insulating barrier between adjacent leads of the plurality of leads.

### BACKGROUND

1. Technical Field

The present invention relates to a semiconductor-integrated electronic device provided with a plurality of leads.

The invention particularly, but not exclusively, relates to a semiconductor-integrated electronic device provided with a plurality of leads and comprising a spacer device for avoiding possible short circuits between adjacent leads and the following description relates to this field of application for simplifying the illustration only.

2. Description of the Related Art

As is well known, semiconductor-integrated electronic devices comprise an integrated circuit realized on dies of semiconductor material which are rigidly mounted on electric interconnection structures and encapsulated by a body of plastic material having protection function.

The electric interconnection structures typically comprise a support plate, usually a thin metallic foil (leadframe), on whose central part the die is placed, and a plurality of rigid metallic conductors electrically connected to predetermined areas of the die through thin metallic wires. The ends of the metallic conductors constitute the leads, or pins, of the semiconductor-integrated electronic device and are outside the body of plastic material and serve as electric connections of the semiconductor-integrated electronic device with an external device, for example a printed mother board.

Generally, the electric interconnection structures are realized in copper or in an iron nickel alloy, called Alloy 42.

The leads projecting from at least one edge of the body of plastic material are bent so that their ends are on a same plane.

Generally, the semiconductor-integrated electronic device comprises two series of leads placed on opposite sides of the body of plastic material.

These leads are generally coated or plated with metallic alloys.

However, especially the use of metallic alloys free of lead, can lead to the formation of short circuits between adjacent leads.

In fact, due to chemical physical interactions between the material constituting the alloy itself and the material of the support plate of the semiconductor-integrated electronic device, ‘whisker’ growth conditions can arise on the leads after that they have been connected to the printed mother board. Whisker defines a crystal filament extending along a particular direction starting from the lead surface coated by the alloy.

This formation phenomenon of the whiskers is favored by the presence of particular temperature and mechanical stress conditions of the plated surface, and, in particular, the areas affected by this crystalline growth are often localized close to areas where the connection leads have undergone a plastic deformation during the molding step.

The growth of the whiskers leads, in extreme situations, to the short-circuiting of the adjacent leads with the consequent passage of the semiconductor-integrated electronic device to the out of order state.

This drawback becomes particularly critical in applications of automotive nature and, in general, in all the areas in which the reliability of the semiconductor-integrated electronic device must be ensured in the long run (for example aerospace applications, storage).

A first prior art embodiment for avoiding the formation of the whiskers is that of pre-plating the leads with nickel-palladium alloys (NiPd).

This first embodiment allows to obtain semiconductor-integrated electronic devices free of whisker, however, the welding of the leads on the printed motherboard is less efficient. Moreover, the devices (called Sockets) normally used for evaluating the functionality of the semiconductor-integrated electronic device are currently of short duration or expensive. Finally, the cost of the semiconductor-integrated electronic device strongly depends on the fluctuations of the palladium cost.

A second prior art embodiment for reducing the formation of the whisker is that of pre-plating the leads with a nickel layer and then electro-plating them with a tin layer.

This embodiment, although allowing a moderating action on the whisker growth, does not however offer any guarantee of having semiconductor-integrated electronic devices free of whisker.

A third prior art embodiment for reducing the formation of the whiskers instead provides that the leads are baked after plating, so as to moderate the stresses introduced by this kind of treatment on the leads themselves.

Even if with this thermal treatment a moderating action on the whisker growth has been verified on semiconductor-integrated electronic devices provided with copper electric interconnection structures, also this embodiment is not exempt from drawbacks. In fact, it is completely ineffective on electric interconnection structures made of iron nickel alloy, and, however, it does not ensure to obtain a semiconductor-integrated electronic device completely free of whisker.

Moreover, when the distance between adjacent leads decreases, the possible formation of short circuits between the leads themselves increases, for example due to deformations.

### BRIEF SUMMARY

An embodiment of this invention is directed to a semiconductor-integrated electronic device comprising a spacer device having such structural and functional characteristics as to avoid short circuits between adjacent leads, overcoming the limits and/or the drawbacks still limiting the semiconductor-integrated electronic devices realized according to the prior art.

The semiconductor-integrated electronic device comprises a spacer device which comprises a plurality of teeth suitable for being interposed between adjacent leads projecting from at least one edge of a body of plastic material of a semiconductor-integrated electronic device so as to form an insulating barrier between adjacent leads.

Advantageously, the spacer device is realized through molding of plastic material in a single piece.

Advantageously, this spacer device is inserted on a body of plastic material of the semiconductor-integrated electronic device after the mounting on an external board and it is fixed through adhesive means, release means, or in a forced way.

The characteristics and the advantages of the semiconductor-integrated electronic device according to the invention will be apparent from the following description of an embodiment thereof given by way of indicative and non-limiting example with reference to the annexed drawings.

### BRIEF DESCRIPTION OF THE SEVERAL VIEWS OF THE DRAWINGS

FIG. 1 is a perspective, exploded view of a semiconductor-integrated electronic device according to one embodiment of the invention,

FIG. 2 is a perspective view from bottom of a detail of the semiconductor-integrated electronic device of FIG. 1, in particular a spacer device,

FIG. 3 is a perspective view from top of the semiconductor-integrated electronic device of FIG. 1,

FIG. 4 is a perspective view from bottom of the semiconductor-integrated electronic device of FIG. 1,

FIG. 5 is a perspective view from bottom of the semiconductor-integrated electronic device of FIG. 1, provided with tightness means,

FIG. 6 is a perspective, exploded view of a semiconductor-integrated electronic device according to a further embodiment of the invention,

FIG. 7 is a perspective view from bottom of a detail of the semiconductor-integrated electronic device of FIG. 6, in particular a spacer device,

FIG. 8 is a perspective view from top of the semiconductor-integrated electronic device according to the further embodiment of the invention, and

FIG. 9 is a perspective view from bottom of the semiconductor-integrated electronic device according to the further embodiment of the invention.

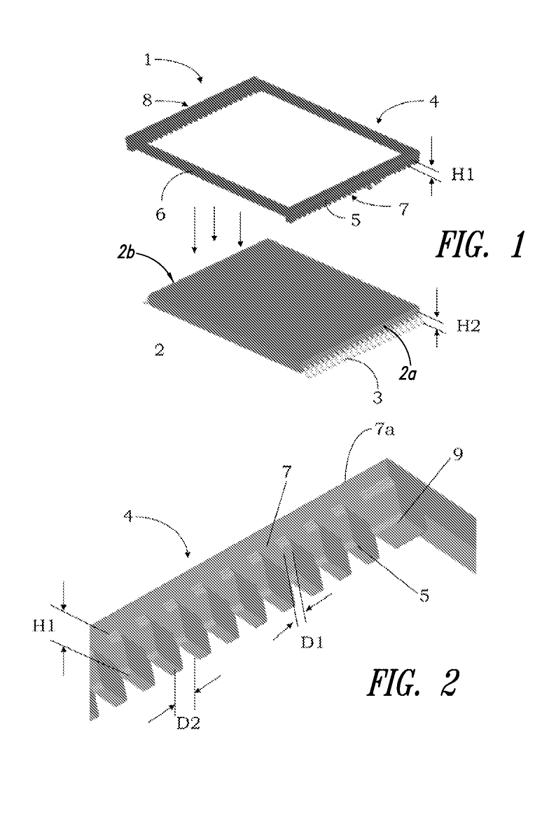

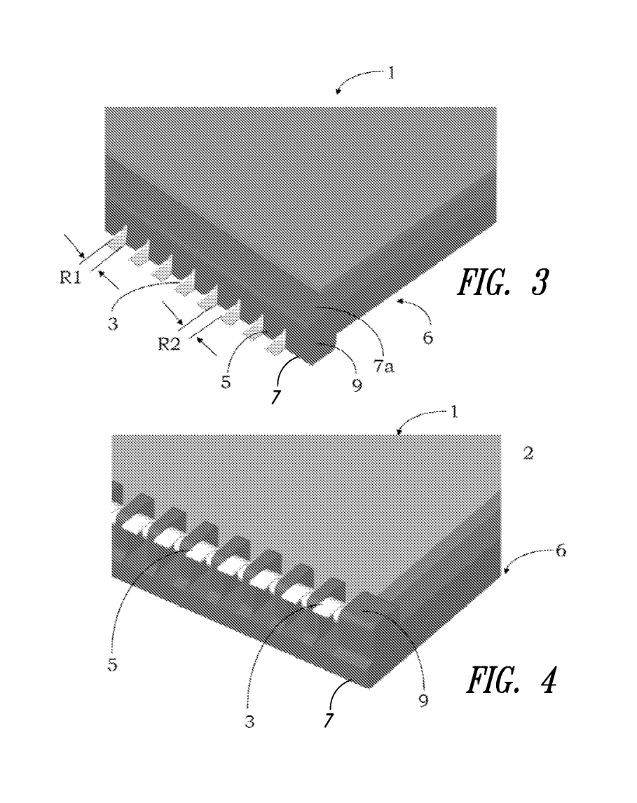

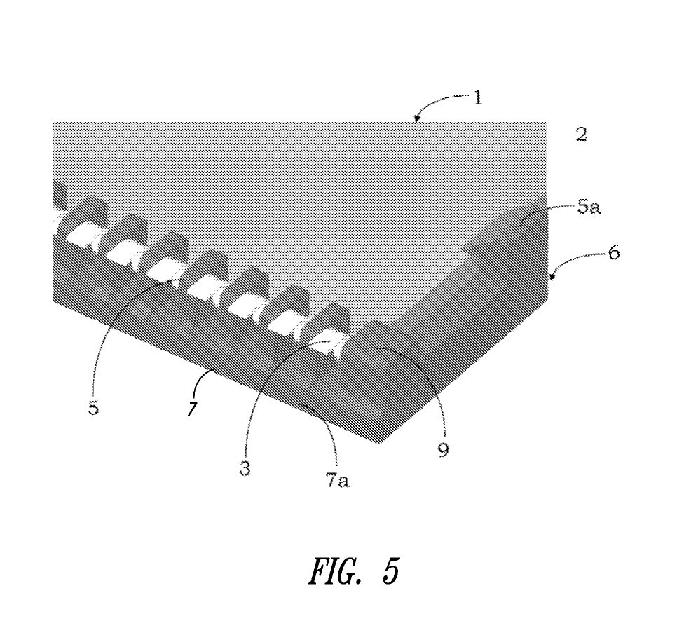

### DETAILED DESCRIPTION

With reference to these figures, a semiconductor-integrated electronic device 1 is described which comprises a body of plastic material 2, usually epoxy resin, which includes a die and an interconnection structure. Leads or pins 3, electrically connected to the interconnection structure, instead project from at least one edge of the body 2 of plastic material.

In particular, these leads 3 are metallic strips of a width R1 projecting from an edge of the body 2 of plastic material, and are, for example, seagull-like shaped.

In particular, the leads 3 are bent so that their ends are on a same plane.

Generally, the body 2 of plastic material has a substantially rectangular shape, and the leads 3 project from one or more edges or sides of the body 2 of plastic material.

Usually, the leads 3 projecting from a same edge of the body 2 of plastic material are in spaced relationship and adjacent to each other.

In particular, these leads 3 are spaced from each other by a distance equal to R2.

These leads 3 are of such dimensions as to allow the connection operations, for example by means of welding, of the semiconductor-integrated electronic device 1 to an external connection device, for example a printed motherboard.

According to an embodiment of the invention, the semiconductor-integrated electronic device 1 comprises a spacer device 4 which comprises a plurality of insulating separators or teeth 5 which are interposed between adjacent leads 3 projecting from a first edge 2a edge of the body 2 in plastic material of the semiconductor-integrated electronic device 1, so as to form an insulating barrier between adjacent leads 3.

Advantageously, this plurality of separators or insulating teeth 5 projects from a first side 7 of a frame 6 of substantially rectangular shape. In particular, the insulating teeth 5 are supported by a base 7a, having an elongated body, the teeth 5 and the base 7a thus realizing a comb. The base 7a is mounted on top of said plurality of teeth 5, co-planar with a top surface of the body 2.

This embodiment of the spacer device 4 allows a quick mounting operation of the spacer device 4 on the body 2 in plastic material.

Advantageously, a second plurality of insulating teeth 5 projects from a second side 8 of the frame 6 opposite to the first side. This second plurality of insulating teeth 5 is interposed between a second plurality of leads 3 projecting from a second edge 2b of the body 2 of plastic material, this second edge being opposite to the first edge.

Advantageously, the plurality of teeth 5 is provided on all the four sides of the frame 6, each tooth 5 being interposed between pairs of leads 3 projecting from the body 2 of plastic material.

In particular, the second side 8 of the frame and the second plurality of teeth 5 are comb-like shaped.

In particular, the teeth 5 of the first and of the second comb project from the frame 6 in a perpendicular direction to the plane whereon the frame 6 lies and they are on its same side.

In essence, the frame 6 with the plurality of teeth 5 realizes a cover of the semiconductor-integrated electronic device 1.

Advantageously, the frame 6 and the teeth 5, which form the spacer device 4, are realized with the same insulating material.

Advantageously, the spacer device 4 is realized through molding of plastic material in a single piece, allowing an easy realization of this spacer device 4, preferably in the form of a stamped plastic gage, advantageously a heat-resistant gage.

Advantageously, the teeth 5 have a substantially parallelepiped shape.

Advantageously, the teeth 5 have a width D1 which is smaller than the distance R2 dividing two adjacent leads.

Moreover, the adjacent teeth 5 belong to a same side of the frame 6 are in spaced relationship to each other by a distance D2 greater than the width R1 of each lead 3, so as not to create interference between the leads 3 and the teeth 5.

Advantageously, this spacer device 4 is provided with fixing means for rigidly fixing to the body 2 of material.

Advantageously, the fixing means comprise adhesive means, which allow a quick and economic fixing of the frame 6 to the body 2 of plastic material.

Advantageously, the fixing means comprise tightness means 5a for fixing, in a release-like way, the frame 6 to the body 2 of plastic material of the semiconductor-integrated electronic device 1.

For example, the frame 6 is provided with at least one hook-like shaped element 5a projecting from a side of the frame 6 which, at the end of the insertion step of the frame 6 onto the body 2 of plastic material, rigidly “hooks” the body 2 of plastic material and prevents the removal of the spacer device 4 from the body 2 of plastic material during the operation of the semiconductor-integrated electronic device 1, as shown in FIG. 5.

In an alternative embodiment, at least one of the teeth 5 could be shaped for acting as tightness means 5a.

For example, two hook-like shaped teeth 5 could be provided for each side of the frame 6 in the most external positions between the first and the second lead 3 and between the last but one and the last one.

Advantageously, the spacer device 4 is shaped for being fitted on the body 2 of plastic material in a forced way.

For example, the dimensions of the frame 6 are smaller than the dimensions of the plastic body 2 so that there is mechanical interference between them.

In this case, the frame 6 will be elastically deformed during the coupling step to the body 2 of plastic material.

For example, the spacer device 4 is fixed onto the body 2 of plastic material after having connected the leads 3 onto an external board, so as not to interfere with the connection operations of the leads 3 to the external board.

Advantageously, the teeth 5 have a height H1 equal to a distance H2 between two ends of each lead 3 allowing the insulation of the whole area comprised between adjacent leads.

Advantageously, each side 7, 8 of the frame is provided with end teeth 9, placed outside the first and second plurality of leads 3, of greater width with respect to the teeth 5 which abut between the leads 3.

According to an embodiment of the invention, when the spacer device 4 is coupled to the body 2 of plastic material, the teeth 5 of the spacer device 4 are placed between the adjacent leads 3.

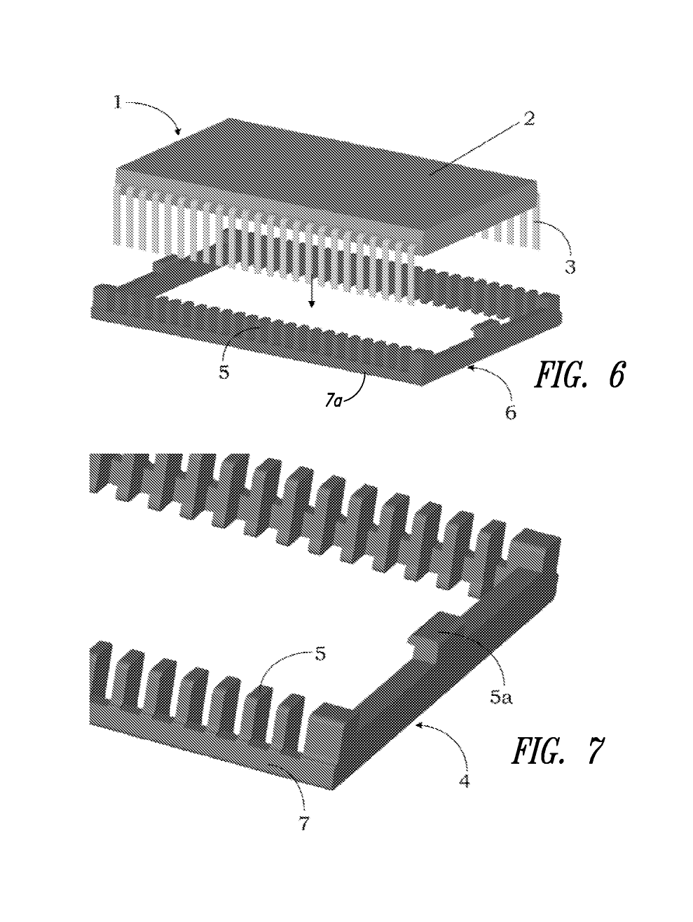

Advantageously according to a further embodiment of the invention, as shown in FIG. 6, insulating teeth 5 are supported by a base 7a, having an elongated body and mounted laterally of said plurality of teeth 5, which extend from both sides of the base 7a, with respect to a plane defined by a top surface of the body 2, as shown in FIG. 7.

As previously, the plurality of teeth 5 is provided on one, two or all the four sides of the frame 6, each tooth 5 being interposed between pairs of leads 3 projecting from the body 2 of plastic material.

Moreover, the frame 6 and the teeth 5 forming the spacer device 4 are realized with the same insulating material, for instance through molding of plastic material in a single piece, preferably in the form of a stamped plastic gage, advantageously a heat-resistant gage.

The spacer device 4 is provided with fixing means for rigidly fixing to the body 2 of material, for instance tightness means 5a for fixing, in a release-like way, the frame 6 to the body 2 of plastic material of the semiconductor-integrated electronic device 1.

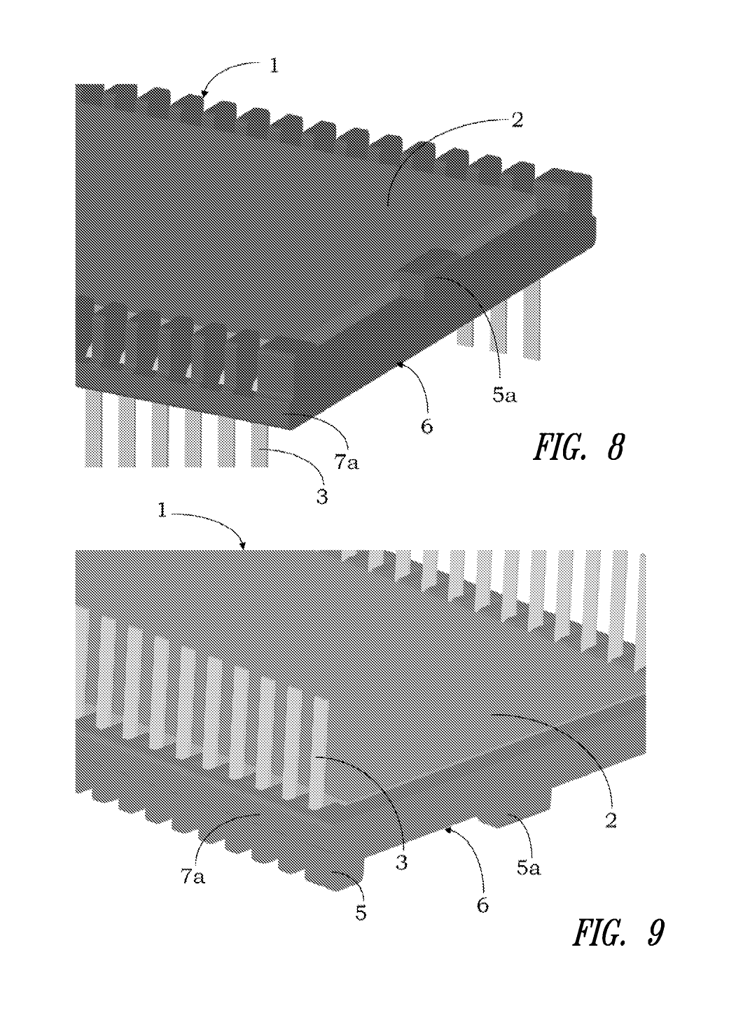

This further embodiment of the spacer device 4, as shown in FIGS. 8 and 9, is advantageously used in case of through hole packages, wherein the leads 3 extend vertically through the package.

Moreover, advantageously according to this further embodiment of the invention, the frame 6 and the teeth 5 form a heat-resistant gage which is inserted on the package or placed on board before the mounting on board step and can be fixed in the position through the adhesive tape or stuck by the package side.

Also in this case, the teeth provided within adjacent pins prevents that a whisker could connect such pins causing the electric fail.

Additional advantages are as follows:
the spacer device 4 is applied prior to or during the mount on board process;
it allows package suppliers to provide customers with the spacer device 4 already in packages; and
it allows board suppliers to provide with a spacer device 4 already in the board, thus simplifying the mount on board step by reducing any handling and mounting flow at the final user's line.

Advantageously according to an embodiment of the invention, the presence of the teeth 5 between the leads 3 ensures that short circuits do not occur between adjacent leads for example because of the whisker growth due to the plating treatments the leads must undergo.

In particular, the use of the spacer device 4 according to an embodiment of the invention is particularly advantageous when the distance between adjacent leads 3 on a same edge of the body 2 of plastic material decreases, since the above problems due to the whiskers can be very evident.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A semiconductor-integrated electronic device comprising:
a body having a first edge;
a plurality of leads, adjacent and in a spaced relationship to each other, projecting from the first edge of the body; and
a spacer device which comprises a base structured to be fixed to an outer surface of the body and a plurality of insulating teeth projecting from base and interposed between the plurality of leads, so as to form an insulating barrier between adjacent leads of the plurality of leads.

2. The semiconductor-integrated electronic of claim 1, wherein the body is made of plastic material.

3. The semiconductor-integrated electronic of claim 1, wherein the body has a substantially rectangular shape, the base includes a frame of substantially rectangular shape, and the plurality of insulating teeth projects from a first side of the frame.

4. The semiconductor-integrated electronic device of claim 3, wherein a further plurality of insulating teeth projects from a second side of the frame opposite to the first side, the first plurality of insulating teeth being interposed between a further plurality of leads projecting from a second edge of the body opposite to the first edge.

5. The semiconductor-integrated electronic device of claim 3, wherein the frame and the plurality of teeth are realized with the same material.

6. The semiconductor-integrated electronic device of claim 5, wherein the frame and the plurality of teeth are integral with each other.

7. The semiconductor-integrated electronic device of claim 1, wherein each tooth of the plurality of teeth has a substantially parallelepiped shape of a width which is smaller than a distance dividing two adjacent leads, the plurality of adjacent teeth being spaced from each other by a distance greater than a width of each lead.

8. The semiconductor-integrated electronic device of claim 1, wherein the spacer device comprises fixing means for fixing the spacer device to the body.

9. The semiconductor-integrated electronic device of claim 1, wherein the spacer device comprises a hook element structured to fix the spacer device onto the body.

10. The semiconductor-integrated electronic device of claim 1, wherein the spacer device is fixed onto the body by an adhesive.

11. The semiconductor-integrated electronic device of claim 1, wherein the spacer device is shaped so as to be forcedly fitted on the body.

12. The semiconductor-integrated electronic device of claim 1, wherein the base has an elongated body, the teeth and the base realizing a comb with the base mounted on top of the plurality of teeth, co-planar with a top surface of the body.

13. The semiconductor-integrated electronic device of claim 1, wherein the base has an elongated body, the teeth and the base realizing a comb with the base mounted laterally of the plurality of teeth, which extend from both sides of the base, with respect to a plane defined by a top surface of the body.

14. A spacer device, comprising:
a base; and
a plurality of insulating teeth projecting from the base and suitable for being interposed between a plurality of leads of a semiconductor-integrated electronic device so as to form an insulating barrier between adjacent leads of the plurality of leads, the leads being adjacent to and spaced apart from each other and projecting from a first edge of the body.

15. The spacer device of claim 14, wherein the base and teeth are made of plastic material.

16. The spacer device of claim 14, wherein the base includes a frame of substantially rectangular shape and the plurality of insulating teeth projects from a first side of the frame.

17. The spacer device of claim 16, wherein a further plurality of insulating teeth projects from a second side of the frame opposite to the first side, the further plurality of insulating teeth being suitable for being interposed between a further plurality of leads projecting from a second edge of the body opposite to the first edge.

18. The spacer device of claim 14, wherein the base and the teeth are realized with the same material.

19. The spacer of claim 18, wherein the base and the teeth are integrally made of a single piece of material.

20. The spacer device of claim 14, wherein the base is shaped so as to be forcedly fitted on the body.

21. The spacer device of claim 14, further comprising fixing means for fixing the spacer device to the body.

22. The spacer device of claim 14, further comprising a hook element structured to fix the spacer device onto the body of plastic material.

23. The spacer device of claim 14, wherein the base has an elongated body, and the teeth and the base form a comb.

24. The spacer of claim 14, wherein base has an elongated body, the teeth and the base realizing a comb with the base mounted laterally of the plurality of teeth, which extend from opposite sides of the base, with respect to a plane defined by a top surface of the base.

25. A semiconductor-integrated electronic device, comprising:
a body;
a plurality of leads spaced apart from each other and projecting from the body; and
a spacer device that includes:
a base;
a plurality of insulating teeth projecting from base and interposed between the plurality of leads, so as to form an insulating barrier between adjacent leads of the plurality of leads; and
fixing means for fixing the base to an outer surface of the body.

26. The semiconductor-integrated electronic of claim 25, wherein the body has a substantially rectangular shape, the base includes a frame of substantially rectangular shape, and the plurality of insulating teeth projects from a first side of the frame.

27. The semiconductor-integrated electronic device of claim 26, wherein a further plurality of insulating teeth projects from a second side of the frame opposite to the first side, the first plurality of insulating teeth being interposed between a further plurality of leads projecting from a second edge of the body opposite to the first edge.

28. The semiconductor-integrated electronic device of claim 25, wherein the fixing means comprise a hook element structured to fix the base onto the body.

29. The semiconductor-integrated electronic device of claim 25, wherein the fixing means includes a frame integral with the base, the frame being shaped so as to be forcedly fitted on the body.

30. The semiconductor-integrated electronic device of claim 25, wherein the base has an elongated body, the teeth and the base realizing a comb with the base mounted co-planar with a top surface of the body and the teeth extending downwardly from the base and between the leads.

31. The semiconductor-integrated electronic device of claim 25, wherein the base has an elongated body, the teeth and the base realizing a comb with the base mounted laterally of the plurality of teeth, which extend from both sides of the base, with respect to a plane defined by a top surface of the body.
